(19) United States
(12) Patent Application Publication
(10) Pub. No.: US 2026/0195499 A1
(43) Pub. Date: Jul. 9, 2026

(54) Simulation Device and Simulation Method

(71) Applicant: Hitachi, Ltd., Chiyoda-ku, Tokyo (JP)

(72) Inventors: Wataru TORIUMI, Tokyo (JP); Takahiro HATORI, Tokyo (JP); Rui NING, Tokyo (JP)

(21) Appl. No.: 19/130,573

(22) PCT Filed: Nov. 18, 2022
(86) PCT No.: PCT/JP2022/042829

§ 371 Date: May 16, 2025

(51) Int. Cl. G06F 30/20; G06Q 10/047

(52) U.S. Cl. CPC G06F 30/20; G06Q 10/047

(57) ABSTRACT

Provided are a simulation device and a simulation method capable of coping with a bottleneck and obtaining a satisfactory human flow simulation result. A simulation device that simulates a human flow includes: a storage unit; and a control unit for simulation, in which the storage unit stores layout information and a human model that holds at least destination information indicating a destination in the layout information, and current position information, and the control unit determines a movement direction of the human model so as to avoid a region in front of a region where opposing persons having different destinations are lined up in succession.

### TECHNICAL FIELD

The present invention relates to a simulation device and a simulation method for simulating a human flow.

### BACKGROUND ART

In recent years, a human flow simulation system capable of reproducing a flow of pedestrians on a computer for the purpose of evaluating countermeasures against problems caused by local concentration of a crowd, such as prior evaluation of an evacuation guidance plan at the time of events or disasters or prior evaluation of a congestion situation accompanying construction of new commercial facilities has attracted attention.

In relation to the human flow simulation system, for example, PTL 1 proposes “obtaining a ratio of the number of moving agents proceeding in one direction and the number of moving agents proceeding in the other direction at a selected edge for each direction, calculating a width size relative to a direction in which the moving agent proceeds from the ratio with respect to a width of the edge, calculating, with respect to each of the moving agents, a population density based on an area of a section which is obtained from a length of a forward region from a position of the moving agent and the width size calculated for the direction in which the agent proceeds, and the moving agent existing in the section for each direction, and calculating, for each moving agent, a movement speed of the moving agent based on a free walking speed of agent information, the calculated population density, and a predetermined parameter” for the purpose of accurately simulating movement by simulating an interaction caused by a difference in proceeding direction.

### CITATION LIST

### Patent Literature

PTL 1: WO 2021/044481 A

### SUMMARY OF INVENTION

### Technical Problem

According to PTL 1, the walking speed is determined based on the number of moving people and the number of people moving in an opposite direction in the edge, but there is no mention of determination of a movement direction for avoiding a contact in a crowded situation. Therefore, for example, in an environment where an obstacle or a narrow portion, which becomes a bottleneck, exists, a complete deadlock sometimes occurs when an opposing flow to the bottleneck occurs.

In view of the above, an object of the present invention is to provide a simulation device and a simulation method capable of coping with a bottleneck and obtaining an acceptable human flow simulation result.

### Solution to Problem

In view of the above, “a simulation device that simulates a human flow includes: a storage unit; and a control unit for simulation, in which the storage unit stores layout information and a human model that holds at least destination information indicating a destination in the layout information, and current position information, and the control unit determines a movement direction of the human model so as to avoid a region in front of a region where opposing persons having different destinations are lined up in succession”.

Further, in the present invention, “a simulation method for simulating a human flow includes: a storage method; and a simulation control method, in which in the storage method, an arbitrary layout and a human model that holds at least destination information indicating a destination in the layout, and current position information are stored, and in the control method, a movement direction of the human model is determined so as to avoid a region in front of a region where opposing persons having different destinations are lined up in succession.”

### Advantageous Effects of Invention

It is possible to provide a simulation device and a simulation method capable of coping with a bottleneck and obtaining an acceptable crowd flow simulation result.

### BRIEF DESCRIPTION OF DRAWINGS

FIG. 1 is a diagram illustrating a configuration example of a simulation device according to an embodiment of the present invention.

FIG. 2 is a diagram illustrating the inside of a building as an example of an environment for which simulation is to be performed.

FIG. 3a is a diagram illustrating a concept of determining a movement direction of a human model in a normal state.

FIG. 3b is a diagram illustrating a case where an opposing person M2 is detected ahead in the movement direction.

FIG. 4a is a diagram illustrating an example of an opposing person cost map when there is one opposing person.

FIG. 4b is a diagram illustrating an example of an opposing person cost map when there are a plurality of opposing persons.

FIG. 5a is a diagram illustrating a concept of determining a movement direction by cost determination.

FIG. 5b is a diagram illustrating a concept of determining the movement direction by cost determination when there is one opposing person.

FIG. 5c is a diagram illustrating a concept of determining the movement direction by cost determination when there are a plurality of opposing persons.

FIG. 6 is a diagram illustrating a processing flow in a prior preparation stage.

FIG. 7 is a diagram illustrating a processing flow during simulation.

### DESCRIPTION OF EMBODIMENTS

Hereinafter, embodiments of the present invention will be described with reference to the drawings.

### First Embodiment

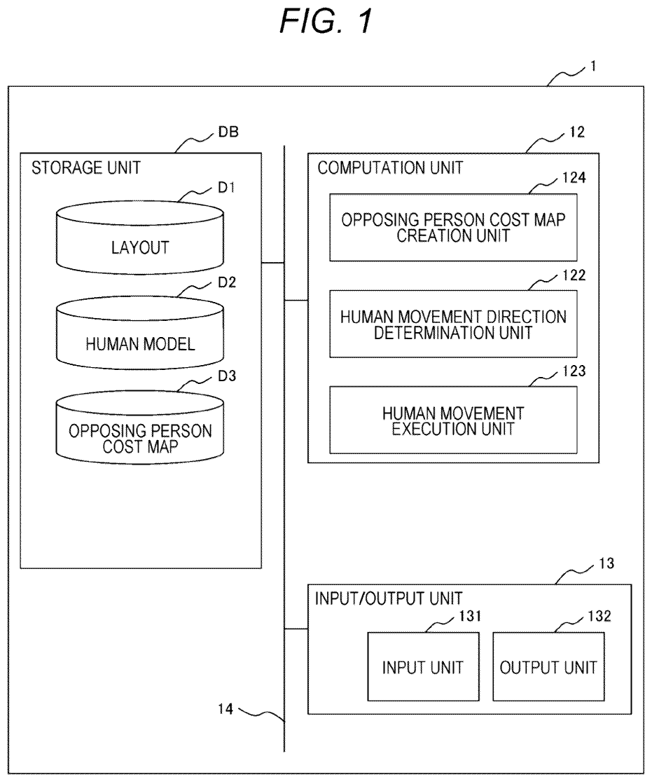

FIG. 1 is a diagram illustrating a configuration example of a simulation device according to a first embodiment of the present invention. A simulation device 1 has a configuration in which a storage unit DB, a computation unit 12, and an input/output device 13 are connected to a bus 14.

Among them, the storage unit DB stores layout information D1 of an environment for which simulation is to be performed, a human model D2 that performs movement behavior under the environment, and an opposing person cost map D3 set in a certain forward range.

In the human model D2, information regarding a human model for which simulation is to be performed is stored for each person. Such information exists as many as the number of people, and include information such as a current position, a destination, and a walking speed of each person.

A functional processing content of the computation unit 12 can be said to include respective processing units including an opposing person cost map creation unit 124, a human movement direction determination unit 122, and a human movement execution unit 123. The input/output device 13 includes an input unit 131 that performs appropriate setting of a simulation condition or the like, and an output unit (display unit) 132 that outputs input setting data and a simulation result.

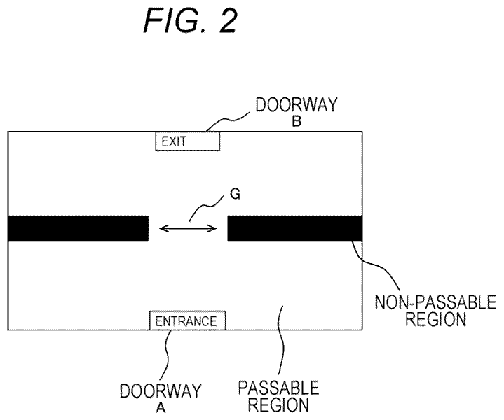

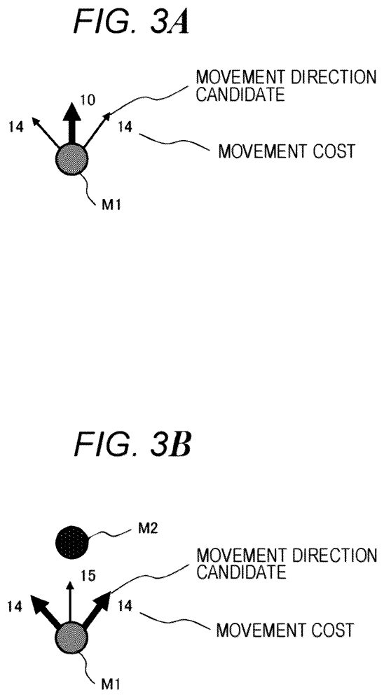

Hereinafter, an operation of the simulation device of FIG. 1 will be described in detail, and several items will be described as a premise. First, as for the environment for which simulation is to be performed, an appropriate place or facility can be selected according to each analysis purpose, and in the embodiment, the inside of a building as illustrated in FIG. 2 is taken as an example. As a method of estimating a movement direction of a person on a simulation model, it is assumed that the estimation is performed using a cost method in FIGS. 3a and 3b.

The building illustrated in plan view of FIG. 2 as an example of the environment for which simulation is to be performed includes a plurality of doorways A and B. The doorway A faces, for example, an external passage or the like, and the doorway B is at a position where an elevator for moving to each floor in the building is installed. Although illustrated in a simplified manner here, a staircase and the like are additionally included as the doorways, and a plurality of doorways may be included. Since a security gate G or the like is installed between the doorways A and B in the building of FIG. 2, a region in plan view is divided into a passable region and a non-passable region.

In order to perform human flow simulation for FIG. 2, for example, it is necessary to set conditions necessary for modeling movement of a person in the building in advance. A setting procedure roughly includes three steps. First, building layout setting in which a layout, a floor dimension, and a height of each floor in the building are set is performed with reference to an architectural drawing or the like. Next, various in-building facilities such as elevators, escalators, security gates, and automatic doors are arranged, and building facility setting in which a specification of each facility is set is performed. Then, an entrance and a doorway of a room are set, and human movement setting in which the number of people moving from one location to another location is set is performed. These steps of setting processing are performed in advance while performing appropriate display using the input/output device 13.

When the building layout setting and the building facility setting are completed, the layout information D1 in which the layout, the floor dimension, and the height of each floor in the building are set is formed and stored as illustrated in FIG. 2.

Furthermore, in the human movement setting on the premise of the above setting, the entrance and the doorway of the room are set, and the number of people moving from one location to another location is set. Information regarding the entrance and the doorway of the room is included in the layout information D1 and managed.

Here, as for handling of the human model at this time, in particular, the cost method is adopted in the present invention as a concept of determining a movement direction of the human model. FIG. 3a is a diagram illustrating the concept of determining the movement direction of the human model in a normal state. Here, for example, eight directions (a front direction, a rear direction, a left direction, and a right direction, and a left-front direction, a right-front direction, a left-rear direction, and a right-rear direction) are set on a floor plane as the movement direction of the human model M1, and a cost is set for each direction. The cost is set in terms of magnitude. Normally, in a case where 10 is set for the front direction, a numerical value larger than 10 is set for other directions. In FIG. 3a, only the front direction, the left-front direction, and the right-front direction are simply described, and 14, which is larger than 10, is set for the left-front direction and the right-front direction. In this setting, a direction for which the cost is lowest is set as a proceeding direction.

In addition, in actual simulation on the premise of such cost setting, when an opposing person M2 is detected ahead in the movement direction as illustrated in FIG. 3b, a cost for a detection direction is adjusted to be higher than an initial setting value of 10, for example, 15. As a result, it is possible to set the movement direction of the human model so as to perform the avoidance action in the left-front direction and the right-front direction or the like according to the principle of setting the direction for which the cost is the lowest as the proceeding direction.

The above is the premise of the simulation technique in the present invention. In the case of the above model, the human model in front of the opposing person can perform the avoidance behavior, but when many human models gather in a narrow portion such as the bottleneck, the occurrence of the avoidance behavior is slow and the avoidance cannot be made, as a result of which a complete deadlock in which a group cannot move due to collision with an opposing group may occur.

Hereinafter, processing in the simulation device in the present invention will be described.

After preparing the contents to be stored, the opposing person cost map creation unit 124 in the computation unit 12 creates the opposing person cost map D3 for each destination of the human model.

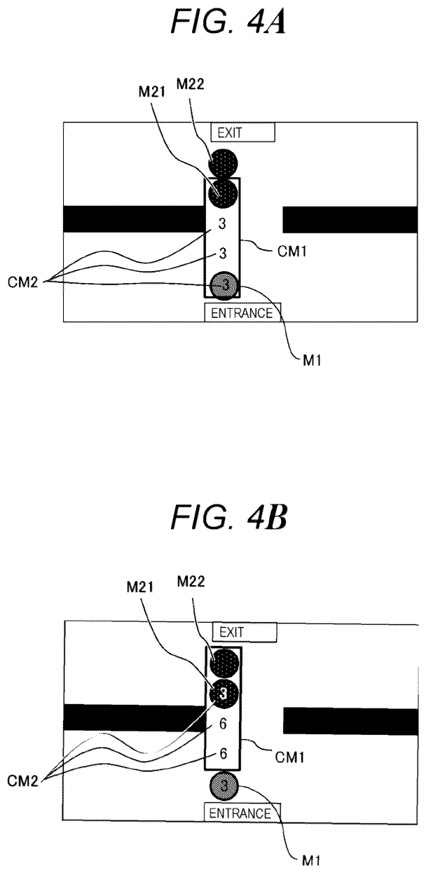

FIGS. 4a and 4b are diagrams illustrating a state in which the opposing person cost map D3 corresponding to a person heading for an exit is created. In these figures, the person heading for the exit is represented as M1, and persons heading for an entrance are represented as M21 and M22. The opposing person cost map D3 is configured by housing a cost value CM2 of the opposing person cost map for each point with respect to a certain forward range CM1 other than the person heading for the exit. In FIG. 4a, a cost value of 3 is added to three points in front of the human model M21. In FIG. 4b, a cost value of 3 is added to three points ahead of the human model M22. In this manner, the cost value is added to a region in front of a person heading for other than a target destination, whereby the opposing person cost map D3 of the target destination is created.

The opposing person cost map D3 may be created not for each destination of the human model but for each movement direction candidate. In a case where there are many destinations, it is expected that a calculation cost and a storage cost can be reduced by this method.

When setting the cost value for each point in the region in front of the person, the cost value may be set to be increased at a point closer to the opposing person.

Furthermore, the cost value added to each point in the region in front of the person may be set to a value smaller than a difference between the smallest value and the second smallest value of a distance cost value for each movement direction of the person. In the case of setting in this manner, the distance cost for another direction becomes larger than that for a direction for which the distance cost becomes the smallest only in a case where a plurality of opposing persons are lined up in succession. Therefore, for example, in a case where one person and a group forming a line face each other, the one person changes the proceeding direction to another direction instead of the group changing the proceeding direction for the one person, so that it is possible to reproduce a more acceptable motion.

Here, for the cost value CM2 of the opposing person cost map, in a case where the opposing person is in the vicinity of a non-passable region such as the bottleneck, processing such as increasing an additional cost may be performed. As a result, an effect of making it easy to cause the avoidance behavior in a narrow region is expected.

As described above, the opposing person cost map creation unit 124 in the computation unit 12 in FIG. 1 performs opposing person cost map creation processing for each destination in each operation cycle of the simulation, and reflects the creation result in the opposing person cost map D3. The reflected content is the cost value CM2 of the opposing person cost map for each point and the like.

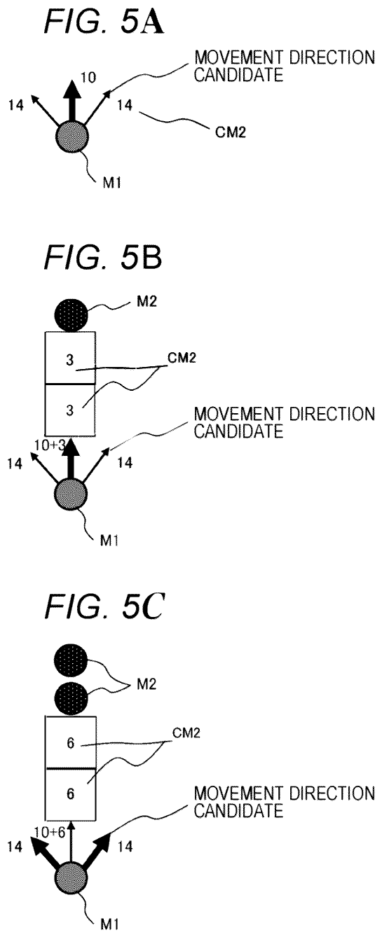

Next, processing in the movement direction determination unit 122 will be described with reference to FIGS. 5a, 5b, and 5c. The movement direction determination unit determines the next movement direction of each human model in each operation cycle of the simulation. FIG. 5a illustrates an example of a magnitude of the cost for each direction in the same normal state as FIG. 3a, and the cost for the other directions is set to 14 higher than 10 which is the cost for the front direction. Therefore, according to the principle of selecting the lower one, the front direction is set as the proceeding direction in the normal state.

FIG. 5b illustrates an example in which there is only one opposing person in the front direction. +3 is added to the cost for the front direction in the normal state with reference to the cost value CM2 of the opposing person cost map, and thus, a movement cost for the front direction becomes 13. However, the movement cost is lower than the cost of 14 for the peripheral directions, the front direction is still selected as the proceeding direction in this case.

FIG. 5c illustrates an example of a case where there is still another opposing person. The cost value CM2 of the opposing person cost map in front of the human model M1 is 6 and is added to the movement cost for the front direction in the normal state, and thus, the movement cost for the front direction becomes 16. At this time, since the movement cost for the front direction becomes 16 higher than 14 which is the cost for the peripheral directions for the first time, one of the left-front direction and the right-front direction is selected as the proceeding direction, and direction change is performed. In a case where the cost value is the same between the movement directions, selection of one of the left direction and the right direction may be performed using a random number or may be performed based on cultural area information input in advance to the layout D1. For example, the right-front direction may be preferentially selected in Japan which follows a right-side walking rule.

The movement direction determination unit 122 has been described above. According to the above processing, the person selects the movement direction so as to avoid a region in front of a point where the opposing persons are lined up in succession, so that movement in which a movement space of the opposing persons is secured can be implemented. Therefore, a complete deadlock can be avoided. This leads to an improvement in accuracy of a simulator and satisfaction for the motion.

Finally, the human movement execution unit 123 will be described. The human movement execution unit 123 changes a position of the human model based on a movement direction of a person determined by the human movement direction determination unit 122. In this way, human flow simulation is implemented by repeating the determination of the movement direction and the position change of the human model for each simulation operation cycle.

In the description of the premise of the above cost setting, the cost for the front direction is set to be lower than the cost for other directions, a cost increase operation is performed according to the presence of the opposing person or the bottleneck, and a direction for which the cost is low is set as the proceeding direction. However, a magnitude relationship thereof and the like may be reversed. That is, the same applies even in a case where the cost for the front direction is set to be higher than the cost for other directions, a cost decrease operation is performed according to the presence of the opposing person or the bottleneck, and a direction for which the cost is high is set as the proceeding direction.

As described above, in the present invention, the opposing person cost map D3 is prepared for each destination of a person, and the cost value is added to each point in the region of in front of the opposing person. In the direction determination, the movement direction is determined with reference to not only a distance to the destination but also a value of the opposing person cost map D3. As a result, since the motion can be changed only when a congestion level is increased, it is possible to make a motion preventing a deadlock at a narrow portion such as the bottleneck without changing human flow characteristics at other points. This leads to an improvement in accuracy of a simulator and satisfaction for the motion.

### Second Embodiment

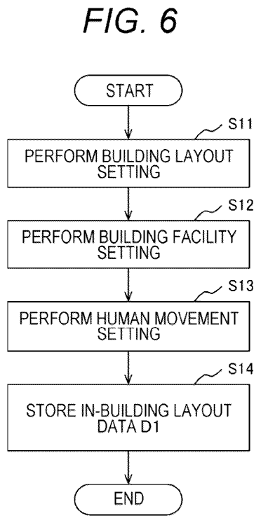

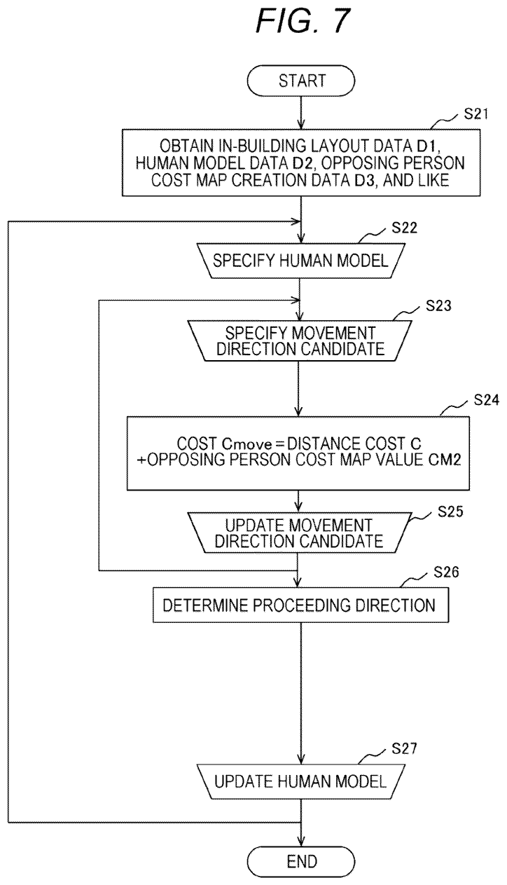

In a second embodiment, a simulation method will be described. FIG. 6 illustrates a processing flow in a prior preparation stage, and FIG. 7 illustrates a processing flow during simulation.

Building layout setting is performed in the first processing step S11 in FIG. 6, building facility setting is performed in processing step S12, and human movement setting is performed in processing step S13, that is, the number of people moving for each departure point and destination point is set for each time. By execution of a series of these steps of processing, each piece of layout information D1 is formed and stored in processing step S14.

In FIG. 7, which illustrates the processing during the simulation, first, in processing step S21, the layout information D1 and a human model D2 of an environment in which the human flow processing is performed, opposing person cost map creation data D3, and the like are obtained. In processing step S22, repetitive processing is performed while changing a human model in the human model D2 until processing step S29. It is assumed that the environment and thus a layout are specified.

In the repetitive processing, in processing step S23, the repetitive processing is performed while changing a movement direction candidate until processing step S25. In processing step S24, a movement cost value Cmove corresponding to the specified movement direction candidate calculated by obtaining the sum of a distance cost C and a cost value CM2 of an opposing person cost map corresponding to a destination of a target human model M.

Processing step S25 is termination determination processing for iteration, and processing step S24 is repeated a number of times corresponding to the number of movement direction candidates.

In processing step S26, the movement cost value Cmove for each movement direction candidate is compared, and a movement direction for which the movement cost value is the smallest is selected to determine the movement direction of the human model M.

Processing step S27 is termination determination processing for iteration, and the above processing is repeated for the human models corresponding to the set number of people.

The processing flow during the simulation has been described above. By repeating the above processing for each simulation operation cycle, the movement direction of the person is determined again so as to avoid the opposing person every time the position of the human model is changed as time passes.

### REFERENCE SIGNS LIST

1 simulation device
DB storage unit
12 computation unit
13 input/output device
14 bus
D1 layout information
D2 human model
D3 opposing person cost map
CM1 certain forward range
CM2 cost value of opposing person cost map
122 human movement direction determination unit
123 human movement execution unit
124 opposing person cost map creation unit
131 input unit
132 output unit (display unit)

1. A simulation device that simulates a human flow, the simulation device comprising:
a storage unit; and
a control unit for simulation,
wherein the storage unit stores layout information and a human model that holds at least destination information indicating a destination in the layout information, and current position information, and
the control unit determines a movement direction of the human model so as to avoid a region in front of a region where opposing persons having different destinations are lined up in succession.

2. The simulation device according to claim 1, wherein
the storage unit includes an opposing person cost map storage unit that stores an opposing person cost map that stores a cost value for each point, and
the control unit includes:
an opposing person cost map generation unit that generates the opposing person cost map by adding the cost value to each point in a certain front region of the human model;
a human movement direction determination unit that calculates a movement cost value using at least the current position information, the cost value of the opposing person cost map, and a distance cost value which is a value based on a distance from a destination for each movement direction candidate of the human model, and determines the movement direction based on a magnitude of the movement cost value; and
a human movement execution unit that changes a current position of the human model in the simulation based on the determined movement direction.

3. The simulation device according to claim 2, wherein the opposing person cost map generation unit sets a narrow portion and an obstacle in the layout information as a bottleneck, and adds the cost value of the opposing person cost map near the bottleneck.

4. The simulation device according to claim 2, wherein the cost value added to each point in front of the human model is set to a value smaller than a difference between a smallest value and a second smallest value of the distance cost value for each movement direction of the human model.

5. The simulation device according to claim 2, wherein
the opposing person cost map generation unit generates a destination-specific opposing person cost map for each destination housed in the human model,
each of the destination-specific opposing person cost map is created without adding the cost value by the human model having the same destination as a destination targeted by the destination-specific opposing person cost map, and
the human movement direction determination unit determines the movement direction by using the destination-specific opposing person cost map corresponding to the destination of the human model.

6. The simulation device according to claim 2, wherein
the opposing person cost map generation unit generates a movement-direction-specific opposing person cost map for each movement direction candidate housed in the human model,
each of the movement-direction-specific opposing person cost map is created without adding the cost value by the human model having the same movement direction as a movement direction targeted by the movement-direction-specific opposing person cost map, and
the human movement direction determination unit determines a final movement direction for each human model by using the movement-direction-specific opposing person cost map corresponding to the movement direction.

7. A simulation method for simulating a human flow, the simulation method comprising:
a storage method; and
a simulation control method,
wherein in the storage method, an arbitrary layout and a human model that holds at least destination information indicating a destination in the layout, and current position information are stored, and
in the control method, a movement direction of the human model is determined so as to avoid a region in front of a region where opposing persons having different destinations are lined up in succession.
